(19) United States
(12) Patent Application Publication
(10) Pub. No.: US 2002/0079985 A1
(43) Pub. Date: Jun. 27, 2002

(54) Integrated transformer for multiple transceivers

(75) Inventors: David Siadat, Trabuco Canyon, CA (US); Carlos A. Laiz, Irvine, CA (US)

Correspondence Address: Steven C. Becker, Foley & Lardner, Firstar Center, 777 East Wisconsin Avenue, Milwaukee, WI, 53202-5367, US

(73) Assignee: Conexant Systems, Inc.

(21) Appl. No.: 09/989,100

(22) Filed: Nov. 21, 2001

Related U.S. Application Data
(60) Provisional application No. 60/252,548, filed on Nov. 22, 2000.

(51) Int. Cl. H03H 7/46

(52) U.S. Cl. 333/126; 333/132

(57) ABSTRACT

A communication circuit includes a first transceiver circuit, a second transceiver circuit, and a transformer. The transformer includes a single core, an input coil, and first and second output coils. The input coil is configured to be coupled to a signal source. The first output coil is coupled to the first transceiver circuit, and the second output coil is coupled to the second transceiver circuit.

### CROSS REFERENCE TO RELATED APPLICATIONS

This application claims the benefit of U.S. Provisional Application No. 60/252,548, filed Nov. 22, 2000.

### STATEMENT REGARDING FEDERALLY SPONSORED RESEARCH OR DEVELOPMENT

Not Applicable.

### FIELD OF THE INVENTION

The present invention relates generally to the fields of asymmetric digital subscriber lines (ADSLs) and home local area networks (HLAN). Further, the present invention relates to circuit components for integrating multiple transceiver circuits.

### BACKGROUND OF THE INVENTION

ADSL, or asymmetric digital subscriber line, is a form of digital subscriber line (DSL) in which the bandwidth available for the one direction is significantly larger than for the other direction, thereby making it asymmetric. Although designed to minimize the effect of cross-talk between the upstream and downstream channels, this setup is well suited for web browsing and client-server applications as well as for some emerging applications such as video-on-demand. The data rate of ADSL depends on the length and quality of the line connecting the end user to the telephone company (telco). Typically the upstream data flow is between 16 and 832 kilobits per second (kbps) while the downstream data flow is between 1.5 and 9 megabits per second. ADSL also provides a voice channel. ADSL can carry digital data, analog voice, and broadcast MPEG video in a variety of implementations to meet customer needs. In home computing, ADSL is becoming an increasingly popular alternative to standard 28.8 kbps or 33.6 kpbs telephone modems when connecting to outside signal sources, such as the Internet.

Another trend in home computing is to network multiple computers within a home using a home local area network or HLAN. An HLAN is a local area network that connects multiple computing systems (e.g., laptop personal computers (PCs), desktop PCs, appliances, audio/visual equipment, Internet browsers, etc.) in a home, home office, or similar environment. An HLAN typically uses the existing telephone lines, coaxial cable lines, or electrical power system lines within a house as the network bus; however, dedicated network lines, such as ethernet lines, may also be installed.

ADSL and HLAN transceiver circuitry each require a transformer between the transceiver circuitry and an input jack (e.g., an RJ11 jack). Each transformer provides isolation between the transceiver circuitry and the input jack. Isolation protects the transceiver circuitry from high voltage spikes (e.g., due to lightning, power surges, or other high voltage phenomena). A capacitor in series with the transformer filters out DC (direct current) signals in the telephone line for telephony applications. The transformer also provides impedance adjustment to present the correct impedance to the telephone line, and provides necessary voltage adjustment. However, each transformer is an expensive component that adds significant cost to the manufacture of a multiple transceiver circuit.

Thus, there is a need for reducing the complexity and cost of multiple transceiver circuitry. Further, there is a need for an improved ADSL/HLAN communication circuit. Further still, there is a need for an ADSL communication circuit having improved functionality and flexibility.

### SUMMARY OF THE INVENTION

According to one exemplary embodiment, a communication circuit includes a first transceiver circuit, a second transceiver circuit, and a transformer. The transformer includes a single core, an input coil, and first and second output coils. The input coil is configured to be coupled to a signal source. The first output coil is coupled to the first transceiver circuit, and the second output coil is coupled to the second transceiver circuit.

According to another exemplary embodiment, a transformer for use in an integrated ADSL/LAN system includes a core and a first circuit coupled to the core. The first circuit is coupleable to a signal source and configured to receive an input signal from the signal source, wherein the input signal includes at least one of an ADSL signal and a LAN signal. The transformer further includes a second circuit coupled to the core configured to receive the ADSL signal and a third circuit coupled to the core configured to receive the LAN signal.

According to yet another exemplary embodiment, a transformer circuit includes a means for providing a path for a magnetic field, a means for receiving an input signal from a signal source, wherein the input signal includes at least one of an ADSL signal and a LAN signal, a means for receiving the ADSL signal via the magnetic field path, and a means for receiving the LAN signal via the magnetic field path.

According to still another exemplary embodiment, a communication circuit for home use includes an ADSL receiver circuit, a LAN receiver circuit, and a transformer. The transformer is configured to receive an ADSL signal from a signal source and to provide the ADSL signal to the ADSL codec and to receive a LAN signal from the signal source and to provide the LAN signal to the LAN codec.

### BRIEF DESCRIPTION OF THE DRAWINGS

The invention will become more fully understood from the following detailed description, taken in conjunction with the accompanying drawings, wherein like reference numerals refer to like parts, in which:

FIG. 1 is a block diagram of a networked home computer system according to an exemplary embodiment;

FIG. 2 is a schematic diagram of an alternative embodiment of a transformer circuit for the system of FIG. 1; and

FIG. 3 is a schematic diagram of an alternative embodiment of a transformer circuit for the system of FIG. 1.

### DETAILED DESCRIPTION OF EXEMPLARY EMBODIMENTS

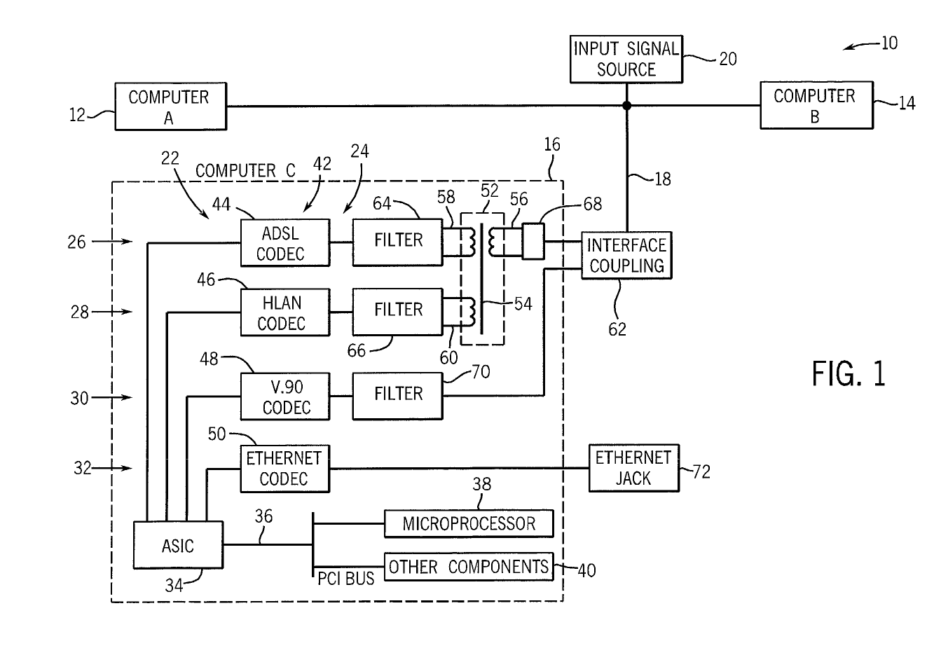

Referring first to FIG. 1, FIG. 1 is a block diagram of a networked home computer system 10 according to an exemplary embodiment. System 10 includes a plurality of computers, such as, computer A 12, computer B 14, and computer C 16. Computers 12, 14, and 16 may be any type of computing device suitable for home or office use, such as, a laptop PC, a desktop PC, appliances, audio/visual equipment, input/output devices, Internet web browser equipment, etc. Fewer or greater than three computers may be coupled to telephone line 18 in alternative embodiments. System 10 further includes a telephone line 18 coupled to an input signal source 20. In this exemplary embodiment, input signal source 20 includes a plain old telephone system (POTS), but may be other types of telephone systems, digital or analog, or other signal sources.

Each of computers 12, 14, and 16 includes suitable interface circuitry for communicating, both transmit and receive, across telephone line 18, with each other and with input signal source 20. An exemplary communication circuit 22 is illustrated in detail in FIG. 1 in computer C 16. It is understood that similar communication circuits may also be utilized in computers 12 and 14.

Communication circuit 22 includes four transceiver circuits 24 integrated therein in this exemplary embodiment. Transceiver circuits 24 include an ADSL (asymmetric digital subscriber line) transceiver circuit 26, a LAN (local area network) transceiver circuit 28, a V.90 modem transceiver circuit 30, and an Ethernet transceiver circuit 32. Transceiver circuits 24 are preferably configured for bidirectional communication with telephone line 18, but may alternatively be configured for one-way communication. An application specific integrated circuit 34 (ASIC) couples transceiver circuits 24 to an internal bus 36 (e.g., a PCI, or peripheral component interconnect, bus, or other bus). A microprocessor 38 and/or other computer components 40 may be coupled to PCI bus 36 for communication therewith. ASIC 34 is, in this embodiment, a P51 ASIC, manufactured by Conexant Systems, Newport Beach, Calif. and is configured to provide communication between transceiver circuits 24 and PCI bus 36. Alternate circuitry, including discrete components, or other semiconductor components may be implemented in place of ASIC 34.

Each of transceiver circuits 24 includes a respective codec (coder/decoder) configured to convert signals between PCI bus 36 and telephone line 18 to and from a respective data format. For example, ADSL codec 44 converts signals to and from an ADSL format. In this exemplary embodiment, ADSL codec may be a 20431 codec manufactured by Conexant Systems, Inc., located in Newport Beach, Calif. An HLAN codec 46 converts signals to and from a local area network format, such as a home local area network format. HLAN codec 46 may be a 11625 HPNA (home phoneline networking alliance) 1.0 codec manufactured by Conexant Systems, Inc., located in Newport Beach, Calif. Alternatively, HLAN codec 46 may operate according to HPNA 2.0 or another HLAN protocol. V.90 codec is configured to convert signals to and from a V.90 modem format. In this exemplary embodiment, a 20463 V.90 codec manufactured by Conexant Systems, Inc., located in Newport Beach, Calif., is implemented, though other codecs may be used. An Ethernet codec 50 is configured to convert signals to and from an Ethernet format, as is known in the art. In this exemplary embodiment, codecs 42 are all implemented on one circuit board or in one interface circuit within computer 16.

As mentioned, each of ADSL transceiver circuit 26 and LAN transceiver circuit 28 utilizes a transformer coupling to input signal source 20. According to one advantageous feature, a single transformer 52 is utilized in this exemplary embodiment to replace multiple transformers which had been used in the past. Transformer 52 includes a core 54, a first coil 56, a second coil 58, and a third coil 60. First coil 56 surrounds core 54 and is coupleable through an interface coupling 62 (e.g., a jack such as a telco R11 jack, or other interface coupling) through telephone line 18 to signal source 20 and to computers 12 and 14. First coil 56 is configured to receive an input signal from signal source 20, or any input signal that includes an ADSL signal and/or a LAN signal. First coil 56 then provides the input signal via a magnetic field path surrounding core 54 to second coil 58 and third coil 60. Second coil 58 also surrounds core 54 and is configured to receive the input signal. Third coil 60 also surrounds core 54 and receives the input signal.

ADSL transceiver circuit 26 includes a filter 64 coupled between second coil 58 and ADSL codec 44. Filter 64 is configured to pass only the ADSL signal, which has a range of between 20 kiloHertz (kHz) and 1.1 MegaHertz (MHz). In this example, filter 64 includes a band pass filter comprising discrete components (e.g., capacitors, inductors, resistors, etc.) configured to perform the functions needed to provide ADSL signal from second coil 58 to ADSL codec 44. A filter 66 is coupled between third coil 60 and HLAN codec 46. Filter 66 is configured to pass only LAN frequencies, such as, 4.5 MHz to 10 MHz. In this exemplary embodiment, filter 64 may be a 2441 band pass filter.

Filters 64 and 66 may further include a hybrid circuit, to provide cancellation between transmit and receive signals to prevent, for example, transmit signals from entering the receive portion of the filter.

Core 54 is configured to operate in a plurality of frequency ranges including an ADSL frequency range and a LAN frequency range. According to one embodiment, core 54 is configured for operation over a wide signal bandwidth (e.g., between 20 kHz and 10 MHz) to cover all frequencies in both the ADSL range and the LAN range. The number of windings and, consequently, the turning ratios of coils 56, 58, and 60 are configured to provide the proper impedance adjustments and voltage adjustments necessary to convert the input signal to a format suitable for codecs 44 and 46. The windings are further configured to reduce crosstalk distortion among the signals received on first coil 56. Core 54 may comprise any suitable substance or combination of substances, including magnetic steel, ceramic, air, or other metals or non-metals. The windings may include copper, aluminum, or other conductive substances.

A buffer 68 coupled between first coil 56 and interface coupling 62 includes circuit components to provide further conditioning of the input signal and output signals to prevent loading effects between the ADSL and LAN signals. Buffer 68 may also provide filtering of the input signal to pass only certain frequencies.

A filter 70 is coupled between interface coupling 62 and V.90 codec 48. Filter 70 includes discrete components configured to pass only frequencies in the V.90 range (e.g., 4 KHz) and further to prevent interference with other signals in the system. Ethernet transceiver circuit 32 further includes an Ethernet jack 72 (e.g., an RJ45 jack). Thus, either Ethernet, or HLAN, or both may be used depending on the application.

In operation, ADSL and HLAN signals are communicated between computers 12, 14, and 16 and input signal source 20 along telephone line 18. Signals are transmitted and received with communication circuit 22 via interface coupling 62. As ADSL and HLAN signals are provided to interface coupling 62, these signals are also provided through buffer 68 to first coil 56. Transformer 52 is configured to generate a magnetic pathway suitable to frequencies in all ranges of ADSL and HLAN communication to allow transmit and receive of ADSL signals between coil 56 and coil 58 and to allow transmit and receive of HLAN signals between coil 56 and coil 60. Codecs 44 and 46 provide proper analog-to-digital conversion and other signal conditioning necessary for the transmit and receive of ADSL and HLAN signals between ASIC 34 and telephone line 18.

According to one advantageous aspect, transformer 52 is an integrated transformer having a single signal input (coil 56) and multiple distinctive signal outputs (e.g., coils 58 and 60). Utilizing integrated transformer 52 provides a substantial reduction in costs when manufacturing communication circuit 32. Integrated transformer 52 further provides a reduction in the complexity of circuitry and eases packaging constraints. Due to the large volumes which are particularly attendant to sales of communication circuits such as communication circuit 22, even a small reduction of cost can result in large savings to manufacturers.

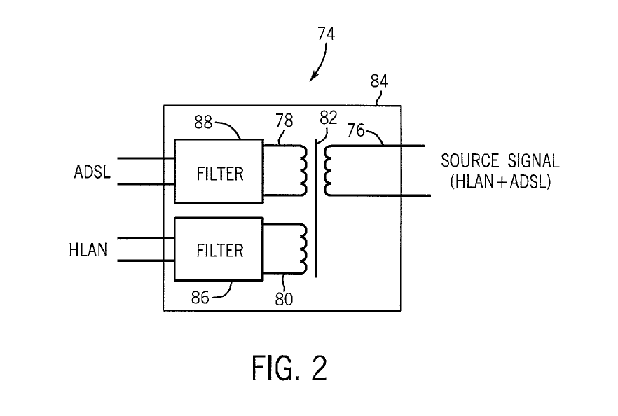

Referring now to FIG. 2, an alternative embodiment of transformer 52 is illustrated. Transformer 74 includes coils 76, 78, and 80, and a core 82 mounted on a substrate 84. Substrate 84 may include a hybrid package, such as a semiconductor package, a ceramic substrate, a printed circuit board, or other board. A filter 88 similar to filter 64 is mounted on substrate 84 and coupled to coil 78. A filter 86 similar to filter 66 is also mounted on substrate 84 and coupled to coil 80. Thus, transformer 74 may be sold along with filter 86, filter 88, and/or other discrete components or filter circuitry coupled to coils 76, 78, and 80.

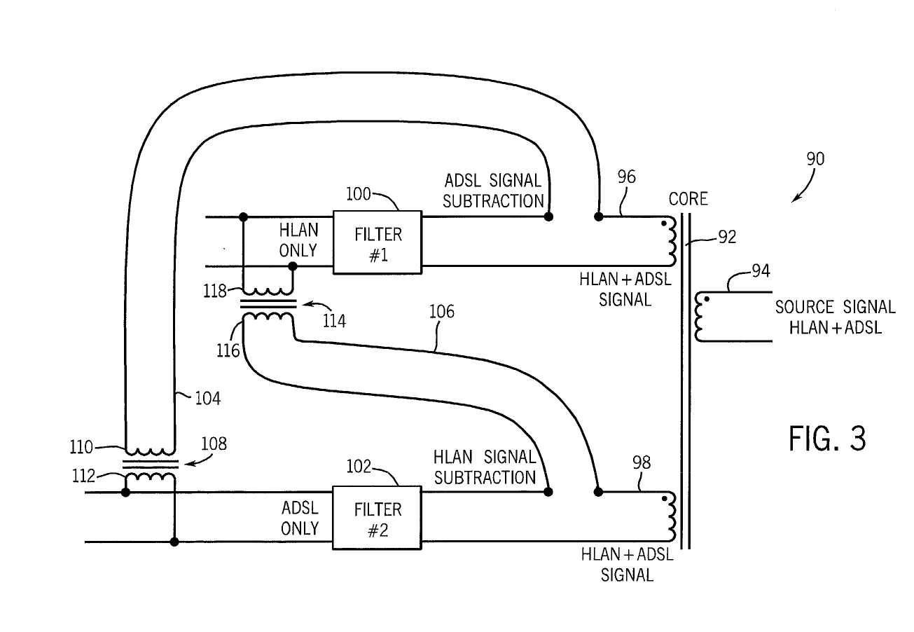

Referring now to FIG. 3, a schematic diagram of an alternative embodiment of a transformer circuit for the system of FIG. 1 is illustrated. A transformer circuit 90 includes a core 92, a source signal input coil 94, an HLAN signal coil 96, and an ADSL signal coil 98. At core 92, coils 94, 96, and 98 are configured to pass both HLAN and ADSL signals therebetween, in one of the many configurations disclosed hereinabove. Circuit 90 further includes a filter circuit 100 and a filter circuit 102 similar in configuration to filter circuit 64 and 66, respectively.

Advantageously, signal subtraction circuits are provided to supplement or replace the signal cancellation function provided by filters 100 and 102 and/or coils 96 and 98. The signal subtraction circuit includes an ADSL signal subtraction circuit 104 and an HLAN signal subtraction circuit 106. ADSL signal subtraction circuit 104 is coupled between ADSL signal coil 96 and filter 100. In particular, ADSL signal subtraction circuit 104 includes a transformer 108 having a first coil 110 in series between HLAN signal coil 96 and filter 100, and a second coil 112 in parallel across the output terminals of filter 102. Similarly, HLAN signal subtraction circuit 106 includes a transformer 114 having a first coil 116 coupled in series between ADSL signal coil 98 and filter 102 and a second coil 118 coupled in parallel across the output terminals of filter 100. Advantageously, this signal subtraction circuit provides additional cancellation of unwanted signals at the outputs of filters 100 and 102.

While the exemplary embodiments illustrated in the FIGS. and described above are presently preferred, it should be understood that these embodiments are offered by way of example only. For example, the transformers disclosed herein may be configured to transmit other signals equivalent to ADSL and LAN signals which are now known or later developed. Further, the transformers disclosed herein may be manufactured as a discrete component or as a part of a larger communication circuit. Accordingly, the present invention is not limited to a particular embodiment, but extends to various modifications that nevertheless fall within the scope of the appended claims.

What is claimed is:

1. A communication circuit, comprising:
a first transceiver circuit;
a second transceiver circuit; and
an integrated transformer having a single core, an input coil, a first output coil, and a second output coil,
wherein the input coil is configured to be coupled to a signal source, the first output coil is coupled to the first transceiver circuit, and the second output coil is coupled to the second transceiver circuit.

2. The communication circuit of claim 1, wherein the first transceiver circuit includes an ADSL codec.

3. The communication circuit of claim 2, wherein the second transceiver circuit includes a LAN codec.

4. The communication circuit of claim 3, wherein the second transceiver circuit includes a home LAN codec.

5. The communication circuit of claim 1, wherein the single core is configured to operate in a plurality of frequency ranges.

6. The communication circuit of claim 5, wherein the first frequency range includes frequencies between 20 kHz and 1.1 MHz and the second frequency range includes frequencies between 4.5 MHz and 10 MHz.

7. The communication circuit of claim 1, further comprising a bandpass filter coupled between the second output coil and the second transceiver circuit.

8. The communication circuit of claim 7, wherein the bandpass filter is configured to pass only frequencies between 4.5 MHz and 10 MHz.

9. The communication circuit of claim 7, further comprising a substrate having the transformer and the bandpass filter disposed thereon.

10. A transformer for use in an integrated ADSL/LAN system, comprising:
a core;
a first circuit coupled to the core and coupleable to a signal source configured to receive an input signal from the signal source, wherein the input signal includes at least one of an ADSL signal and a LAN signal;
a second circuit coupled to the core configured to receive the ADSL signal; and
a third circuit coupled to the core configured to receive the LAN signal.

11. The transformer of claim 10, wherein the core is configured to operate in a plurality of frequency ranges, wherein a first frequency range includes an ADSL frequency and a second frequency range includes a LAN frequency.

12. The transformer of claim 11, wherein the first frequency range includes frequencies between 20 kHz and 1.1 MHz and the second frequency range includes frequencies between 4.5 MHz and 10 MHz.

13. The transformer of claim 10, wherein the second circuit is configured to provide the ADSL signal to an ADSL codec.

14. The transformer of claim 13, wherein the third circuit is configured to provide the LAN signal to a LAN codec.

15. The transformer of claim 14, further comprising a bandpass filter coupled between the third circuit and the LAN codec configured to pass only frequencies between 4.5 MHz and 10 MHz.

16. The transformer of claim 10, wherein the first circuit, second circuit, and third circuit each include a coil of wire surrounding the core.

17. A transformer circuit, comprising:
means for providing a path for a magnetic field;
means for receiving an input signal from a signal source, wherein the input signal includes at least one of an ADSL signal and a LAN signal;
means for receiving the ADSL signal via the magnetic field path; and
means for receiving the LAN signal via the magnetic field path.

18. The transformer of claim 17, wherein the means for providing a path includes a transformer core.

19. The transformer of claim 17, wherein the means for receiving an input signal includes an RJ11 jack.

20. The transformer of claim 17, wherein the means for providing a path includes means for operating in a plurality of frequency ranges, wherein a first frequency range includes an ADSL frequency and a second frequency range includes a LAN frequency.

21. The transformer of claim 20, wherein the first frequency range includes frequencies between 20 kHz and 1.1 MHz and the second frequency range includes frequencies between 4.5 MHz and 10 MHz.

22. The transformer of claim 17, wherein the means for receiving an input signal, the means for receiving the ADSL signal, and the means for receiving a LAN signal each includes a coil of wire having plurality of turns.

23. A communication circuit for home use, comprising:
an ADSL transceiver circuit;
a LAN transceiver circuit; and
a transformer configured to receive an ADSL signal from a signal source and to provide the ADSL signal to the ADSL codec and to receive a LAN signal from the signal source and to provide the LAN signal to the LAN codec.

24. The communication circuit of claim 23, wherein the transformer includes a first coil coupleable to the signal source, a second coil coupled to the ADSL receiver circuit, and a third coil coupled to the LAN receiver circuit.

25. The communication circuit of claim 23, wherein the LAN receiver circuit is a Home LAN receiver circuit.

26. The communication circuit of claim 23, further comprising a bandpass filter coupled between the transformer and the LAN receiver circuit configured to pass only frequencies between 4.5 MHz and 10 MHz.

27. The communication circuit of claim 26, further comprising a substrate having the transformer and the bandpass filter disposed thereon.

28. The communication circuit of claim 23, wherein the ADSL receiver circuit includes an ADSL codec.

29. The communication circuit of claim 23, wherein the transformer includes a core configured to operate in a plurality of frequency ranges, wherein a first frequency range includes an ADSL frequency and a second frequency range includes a LAN frequency.
